(19) United States
(12) Patent Application Publication
(10) Pub. No.: US 2024/0222493 A1
(43) Pub. Date: Jul. 4, 2024

(54) SILICON CARBIDE SEMICONDUCTOR DEVICE

(71) Applicant: FUJI ELECTRIC CO., LTD., Kanagawa (JP)

(72) Inventor: Masakazu BABA, Matsumoto-city (JP)

(21) Appl. No.: 18/491,802

(22) Filed: Oct. 23, 2023

(30) Foreign Application Priority Data
Dec. 28, 2022 (JP) 2022-212203

(51) Int. Cl. H01L 29/78; H01L 29/06; H01L 29/10; H01L 29/16

(52) U.S. Cl. CPC H01L 29/7806; H01L 29/0696; H01L 29/1095; H01L 29/1608

(57) ABSTRACT

Provided is a silicon carbide semiconductor device comprising a transistor portion and a diode portion, comprising: a semiconductor substrate; a plurality of trench portions that are provided on a front surface of the semiconductor substrate; a drift region of a first conductivity type that is provided on the semiconductor substrate; and a second conductivity type region that covers a side wall and a bottom of a trench portion in the diode portion; wherein the transistor portion and the diode portion are alternately arrayed along an extending direction of the trench portion in a mesa portion that is sandwiched between the plurality of trench portions.

The contents of the following patent application(s) are incorporated herein by reference:
NO. 2022-212203 filed in JP on Dec. 28, 2022

### BACKGROUND

### 1. Technical Field

The present invention relates to a silicon carbide semiconductor device.

### 2. Related Art

Patent document 1 describes that by providing a parasitic Schottky barrier diode in parallel to a parasitic pn diode between a source and a drain, the parasitic Schottky barrier diode can be turned on before the parasitic pn diode is turned on when a MOSFET is in an off state.

### PRIOR ART DOCUMENT

### Patent Document

Patent Document 1: Japanese Patent Application Publication No. 2018-107168
Patent Document 2: Japanese Patent Application Publication No. 2019-160898

### BRIEF DESCRIPTION OF THE DRAWINGS

FIG. 1 is a representative drawing of an example of an upper surface of a silicon carbide semiconductor device 100.

FIG. 2A is a representative drawing of an example of a Y-Z cross section of the silicon carbide semiconductor device 100.

FIG. 2B is a representative drawing of an example of a Y-Z cross section of the silicon carbide semiconductor device 100.

FIG. 2C is a representative drawing of an example of a Y-Z cross section of the silicon carbide semiconductor device 100.

FIG. 2D is a representative drawing of an example of an X-Z cross section of the silicon carbide semiconductor device 100.

FIG. 2E is a representative drawing of an example of an X-Z cross section of the silicon carbide semiconductor device 100.

FIG. 2F is a representative drawing of an example of an X-Z cross section of the silicon carbide semiconductor device 100.

FIG. 3A is a representative drawing of a modification example of an upper surface of the silicon carbide semiconductor device 100.

FIG. 3B is a representative drawing of a modification example of a Y-Z cross section of the silicon carbide semiconductor device 100.

FIG. 4 is a representative drawing of a modification example of an upper surface of the silicon carbide semiconductor device 100.

### DESCRIPTION OF EXEMPLARY EMBODIMENTS

Hereinafter, embodiments of the present invention will be described, but the embodiments do not limit the invention according to the claims. In addition, not all of the combinations of features described in the embodiments are essential to the solution of the invention.

In the present specification, one side in a direction parallel to a depth direction of a semiconductor substrate is referred to as an “upper” side, and the other side is referred to as a “lower” side. One of two main surfaces of a substrate, a layer, or other members is referred to as an “upper surface”, and the other surface is referred to as a “lower surface”. “Upper”, “lower”, “front”, and “back” directions are not limited to a direction of gravity, or a direction of an attachment to a substrate or the like when a semiconductor device is mounted.

As used herein, technical matters may be described with orthogonal coordinate axes consisting of an X axis, a Y axis, and a Z axis. In this specification, a surface parallel to the upper surface of a semiconductor substrate is defined as an X-Y surface, and the depth direction of the semiconductor substrate is defined as the Z axis.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, in a layer or a region specified with N or P, electrons or holes are meant to be majority carriers, respectively. Also, ‘+’ and ‘−’ attached on ‘N’ and ‘P’ respectively mean that the higher doping concentration and the lower doping concentration than the layer or region to which it is not attached.

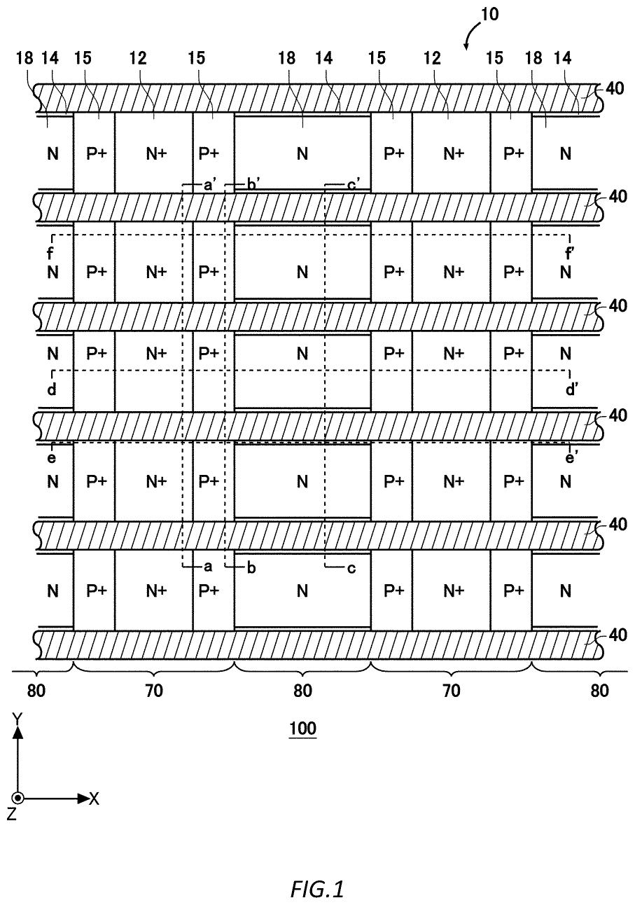

FIG. 1 is a representative drawing of an example of an upper surface of a silicon carbide semiconductor device 100. The silicon carbide semiconductor device 100 may be a power semiconductor device which controls a high voltage and/or a large current. As an example, the silicon carbide semiconductor device 100 is a MOSFET.

The silicon carbide semiconductor device 100 has a semiconductor substrate 10, and includes an active portion and an edge termination structure (not shown) on the semiconductor substrate 10. The silicon carbide semiconductor device 100 in the present example includes a transistor portion 70 and a diode portion 80 in the active portion. The silicon carbide semiconductor device 100 in the present example includes a source region 12, a base region 14, a contact region 15, a drift region 18 and a gate trench portion 40 in a front surface 21 of the semiconductor substrate 10.

The semiconductor substrate 10 is formed of silicon carbide, and has the front surface 21. The semiconductor substrate 10 may be formed by an epitaxial deposition. As an example, a crystal structure of the semiconductor substrate 10 is 4H—SiC. In FIG. 1, the X axis may be an [11-20] direction of the semiconductor substrate 10 which is formed of silicon carbide, the Y axis may be a [1-100] direction of the semiconductor substrate 10, and the Z axis may be a [000-1] direction of the semiconductor substrate 10.

The active portion is provided in the semiconductor substrate 10. The active portion may be a region in which a main current flows when the silicon carbide semiconductor device 100 is in operation. As an example, the active portion has a Metal-Oxide Semiconductor Field-Effect Transistor (MOSFET) structure, but is not limited thereto.

In the semiconductor substrate 10, the edge termination structure is provided on the outer circumference of the active portion. The edge termination structure may reduce electric field strength on the upper surface side of the semiconductor substrate 10. As an example, the edge termination structure has a JTE (Junction Termination Extension) structure. As a modification example, the edge termination structure may include a guard ring, a field plate, a RESURF (reduced surface fields) and combinations thereof.

A trench structure is formed on an upper surface side of the silicon carbide semiconductor device 100. In particular, a plurality of gate trench portions 40 are formed on the front surface 21 of the semiconductor substrate 10.

The drift region 18 is a region of the first conductivity type which is provided in the semiconductor substrate 10. The drift region 18 of the present example is of N type, as an example. The drift region 18 may be provided by performing an epitaxial deposition of silicon carbide while doping an N type dopant. As an example, the N type dopant is a nitrogen atom. A doping concentration of the drift region 18 of the present example may be lower than a doping concentration of a buffer region 24 described below.

The base region 14 is a region of a second conductivity type which is provided to extend in a depth direction of the semiconductor substrate 10 on the front surface 21 of the semiconductor substrate 10. The base region 14 in this example is of P type, as an example. The base region 14 is provided in direct contact with a side wall of the gate trench portion 40 on the front surface 21 of the semiconductor substrate 10 in the diode portion 80. The base region 14 is provided on a portion in the transistor portion 70, which is above the drift region 18 and below the source region 12 and the contact region 15.

The base region 14 may be provided by performing an epitaxial deposition of silicon carbide above the drift region 18 while doping a P type dopant. As an example, the P type dopant is an aluminum atom. A doping concentration of the base region 14 of the present example may be higher than a doping concentration of the drift region 18. In an example, the doping concentration of the base region 14 may be 2×10¹⁶ cm⁻³ or more, or may be 2×10¹⁷ cm⁻³ or less.

The source region 12 is a region of the first conductivity type provided on the front surface 21 of the semiconductor substrate 10. The source region 12 of the present example is of N+ type, as an example. The source region 12 may be in direct contact with the side wall of the gate trench portion 40. The source region 12 of the present example is provided to extend from the side wall of one adjacent gate trench portion 40 to the side wall of the other gate trench portion 40 in an arrangement direction of the gate trench portion 40. The source region 12 may be provided to sandwich the gate trench portion 40 to face another source region 12. That is, the source region 12 may be provided in a stripe shape in the arrangement direction of the gate trench portion 40 in a top view. In an example, the base region 14 may be provided between the source region 12 and the side wall of the gate trench portion 40.

The source region 12 may be formed by forming a mask such as a photoresist on the front surface 21 of the semiconductor substrate 10 and performing an ion implantation from the front surface 21 of the semiconductor substrate 10. The source region 12 may be formed on an epitaxial layer of the semiconductor substrate 10. As an example, a dopant for forming the source region 12 may be phosphorous or nitrogen. The source region 12 may be formed by a single step of ion implantation, or may be formed by two or more steps of ion implantations.

The doping concentration of the source region 12 of the present example may be higher than the doping concentration of the drift region 18. In an example, the doping concentration of the source region 12 may be 1×10¹⁸ cm⁻³ or more, or may be 1×10²¹ cm⁻³ or less.

The contact region 15 is a region of the second conductivity type provided on the front surface 21 of the semiconductor substrate 10. The contact region 15 in the present example is of P+ type, as an example. The contact region 15 may be provided to extend from the side wall of one adjacent gate trench portion 40 to the side wall of the other gate trench portion 40 in an arrangement direction of the gate trench portion 40. The contact region 15 may be provided to sandwich the gate trench portion 40 to face another contact region 15. That is, the contact region 15 may be provided in a stripe shape in the arrangement direction of the gate trench portion 40 in a top view.

The contact region 15 may be formed by forming a mask such as a photoresist on the front surface 21 of the semiconductor substrate 10 and performing an ion implantation from the front surface 21 of the semiconductor substrate 10. The contact region 15 may be formed on an epitaxial layer of the semiconductor substrate 10. A dopant for forming the contact region 15 may be aluminum or boron. The contact region 15 may be formed by a single step of ion implantation, or may be formed by two or more steps of ion implantations.

The doping concentration of the contact region 15 of the present example may be higher than the doping concentration of the drift region 18, or may be higher than the doping concentration of the base region 14. In an example, the doping concentration of the contact region 15 may be 1×10¹⁹ cm⁻³ or more, or may be 1×10²⁰ cm⁻³ or less.

As shown in FIG. 1, the source region 12 and the contact region 15 may be in direct contact with each other in the transistor portion 70. In an example, the source region 12 and the contact region 15 may be separated from each other by providing the base region 14 between the source region 12 and the contact region 15 in the transistor portion 70. In an example, the source region 12 and the contact region 15 may be separated from each other by a width greater than 0 μm and 0.2 μm or less in an extending direction of the gate trench portion 40.

The transistor portion 70 is a region in which the source region 12 or the contact region 15 is provided on the front surface 21 of the semiconductor substrate 10. In the present example, the transistor portion 70 is a MOSFET.

The diode portion 80 is a region in which no source region 12 or contact region 15 is provided on the front surface 21 of the semiconductor substrate 10. In the diode portion 80 of the present example, a region of a first conductivity type is provided, which can configure a Schottky connection to the front surface 21 of the semiconductor substrate 10. The region of the first conductivity type which can configure the Schottky connection may be the drift region 18, or may be another region which can be formed by ion implantation of a dopant. In the diode portion 80, the base region 14 may be provided on the front surface 21 of the semiconductor substrate 10. The diode portion 80 of the present example may be a Schottky barrier diode (SBD).

In the example of FIG. 1, the transistor portion 70 and the diode portion 80 are alternately arranged along a trench extending direction (in the present example, the X axis direction) in mesa portions sandwiched by a plurality of gate trench portions 40. The active portion in another example may be provided with only one of the transistor portion 70 and the diode portion 80.

The transistor portion 70 and the diode portion 80 may have a longitudinal length in each arrangement direction. In other words, the length of the transistor portion 70 in the Y axis direction is greater than the width in the X axis direction. Similarly, the length of each of the diode portions 80 in the Y axis direction is greater than the width in the X axis direction. The extending direction of the transistor portion 70 and the diode portion 80 may be the same as the arrangement direction of the gate trench portion 40.

As in FIG. 1, by arranging the transistor portion 70 and the diode portion 80 to be in direct contact with each other, a voltage loaded to the transistor portion 70 in a case of reverse conducting can be clamped to the diode portion 80, to prevent a parasitic diode in the transistor portion 70 from being turned on. In this way, hole injection to the drift region 18 from the contact region 15 and the base region 14 is reduced and extension of stacking fault due to recombination is suppressed, and thus characteristic deterioration of the silicon carbide semiconductor device 100 due to the extension of the stacking fault can be suppressed.

In addition, as in FIG. 1, by alternately arranging the transistor portion 70 and the diode portion 80 along the trench extending direction, the diode portion 80 can be incorporated without changing the cell pitch (the interval between the adjacent gate trench portions 40). In this way, a ratio of the transistor portion 70 to the diode portion 80 in the silicon carbide semiconductor device 100 can be adjusted finely.

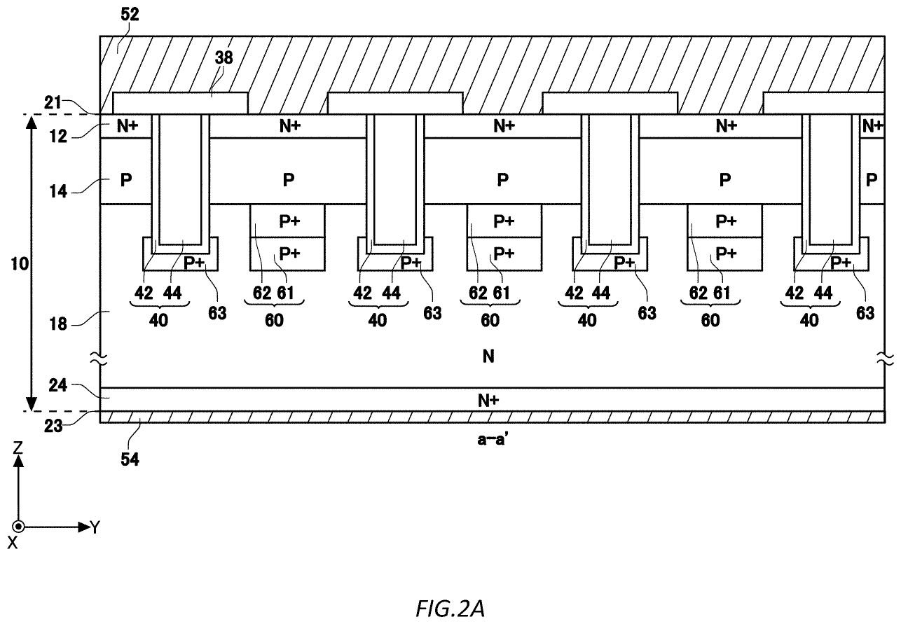

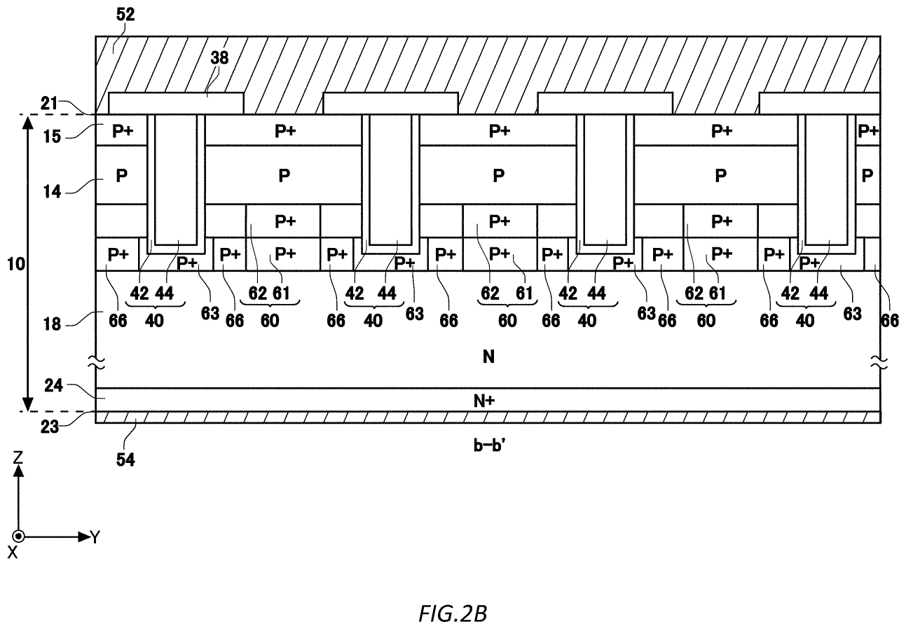

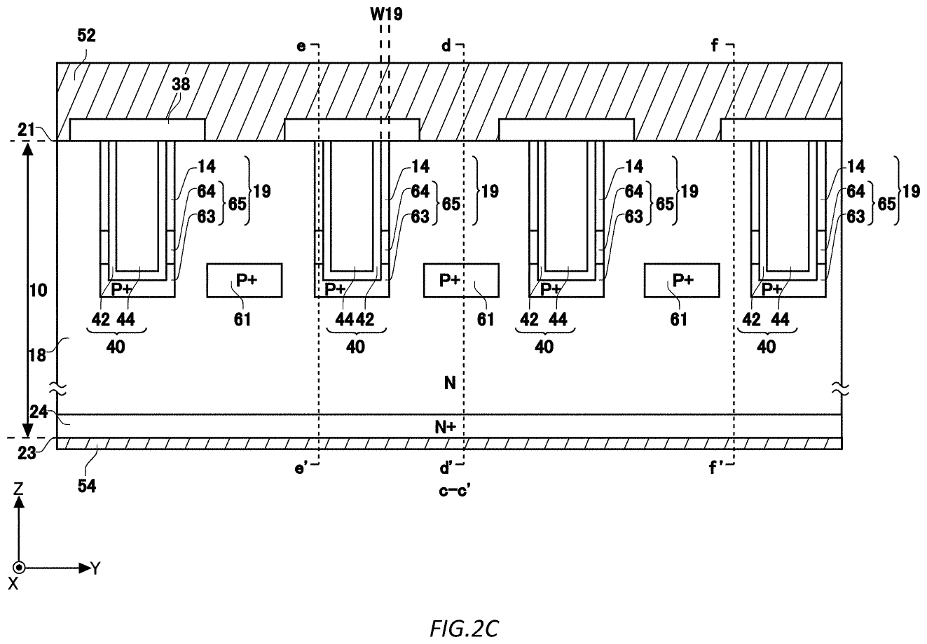

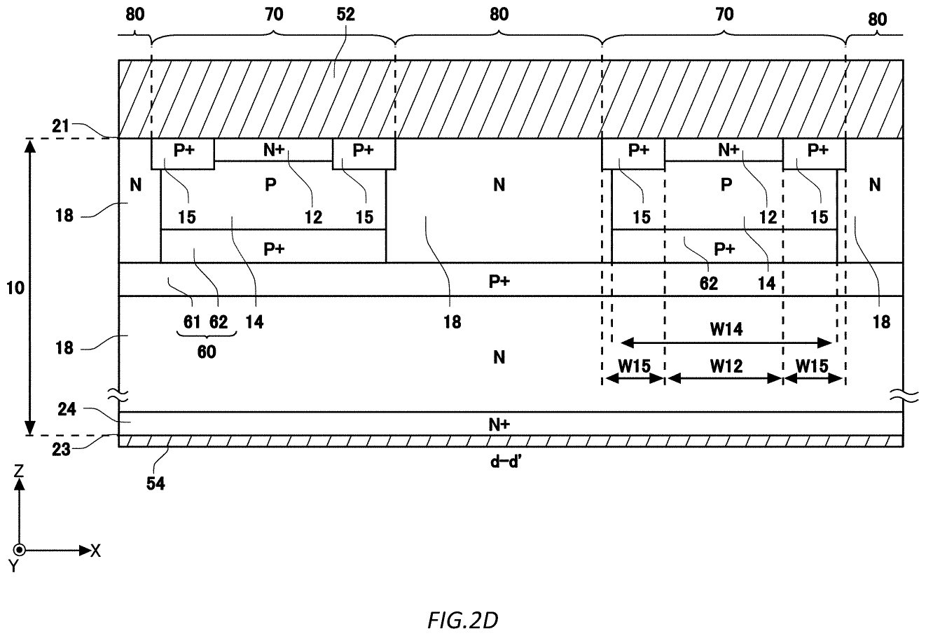

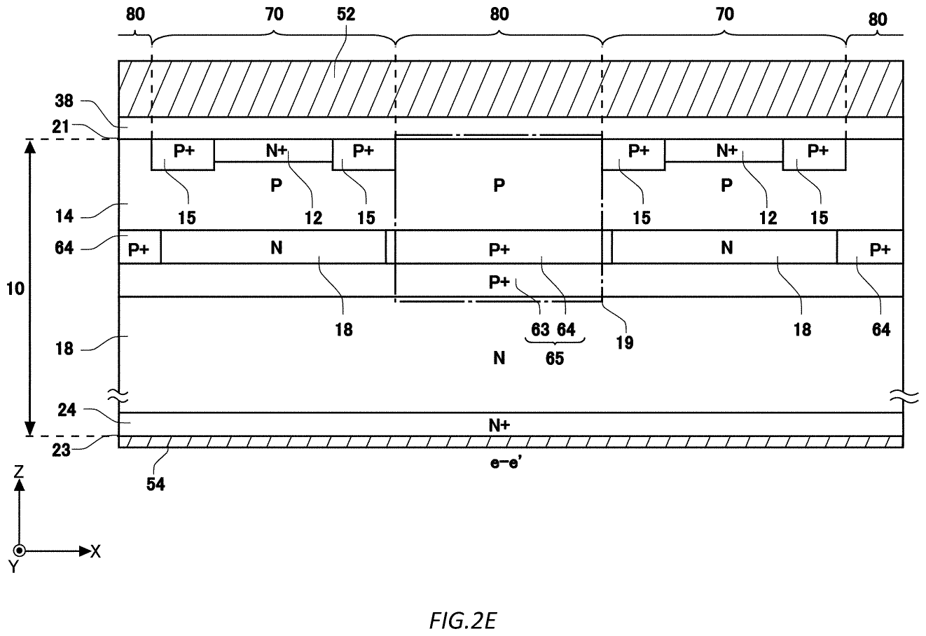

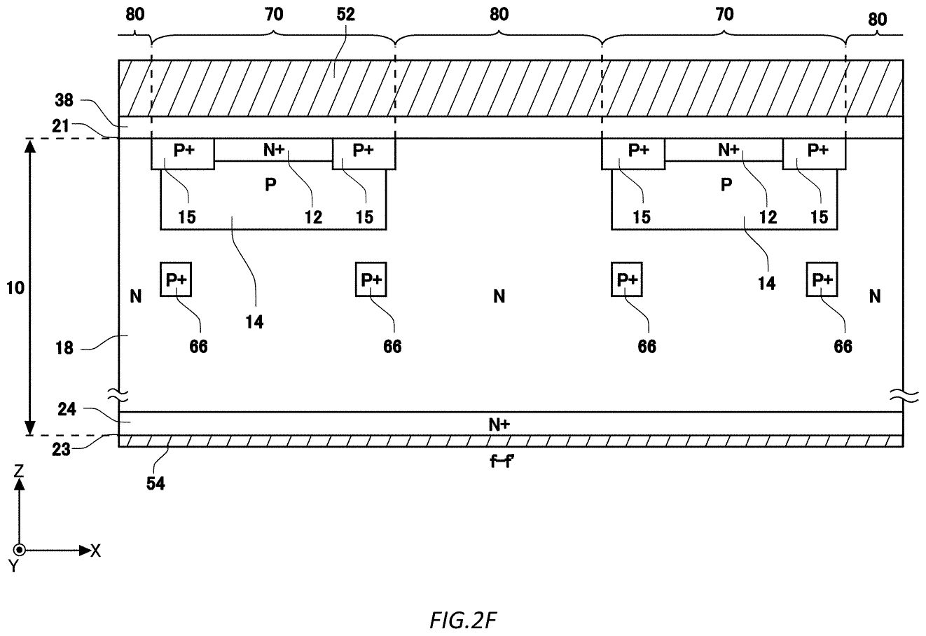

FIG. 2A is a representative drawing of an example of a Y-Z cross section of the silicon carbide semiconductor device 100 on the a-a′ line of FIG. 1. FIG. 2A is a Y-Z cross-sectional view of a region of the silicon carbide semiconductor device 100, in which the source region 12 is provided in a top view. The silicon carbide semiconductor device 100 of the present example includes a source region 12, a base region 14, a drift region 18, a buffer region 24, a dielectric film 38, a gate trench portion 40, a source electrode 52, a drain electrode 54, a mesa body region 60 and a first trench body portion 63.

The buffer region 24 is a region of the first conductivity type which is provided on a back surface 23 of the semiconductor substrate 10. The buffer region 24 is provided below the drift region 18. The buffer region 24 in this example is of N+ type, as an example. The buffer region 24 may be a silicon carbide substrate which is formed of N+ type silicon carbide.

The gate trench portion 40 is provided on the front surface 21 of the semiconductor substrate 10. The gate trench portion 40 may be provided to penetrate the base region 14 to reach the drift region 18. A configuration in which the gate trench portion 40 penetrates the base region 14 is not limited to a configuration which is manufactured by forming the base region 14 and then forming the gate trench portion 40. A configuration in which the base region 14 is formed on the side wall of the gate trench portion 40 after the gate trench portion 40 is formed is also included in the configuration in which the gate trench portion 40 penetrates the base region 14. The bottom of the gate trench portion 40 may be covered by the first trench body portion 63 described below.

The gate trench portion 40 includes a gate dielectric film 42 and a gate conductive portion 44. The gate dielectric film 42 is formed to cover the inner wall of the gate trench portion 40. The gate dielectric film 42 may be formed by oxidizing a semiconductor on the inner wall of the gate trench portion 40.

The gate conductive portion 44 is formed inside the gate trench portion 40 in an inner side than the gate dielectric film 42. The gate dielectric film 42 is configured to insulate the gate conductive portion 44 and the semiconductor substrate 10. The gate conductive portion 44 is formed of a conductive material such as polysilicon. On the front surface 21 of the semiconductor substrate 10, the gate trench portion 40 is covered by the dielectric film 38.

The source electrode 52 is set to a source potential and is provided above the semiconductor substrate 10 to sandwich the dielectric film 38. The source electrode 52 is formed of a material including metal. The source electrode 52 may include a barrier metal. At least partial region of the source electrode 52 may be formed of metal such as aluminum (Al), or metal alloy such as an aluminum-silicon alloy (AlSi) or an aluminum-silicon-copper alloy (AlSiCu).

The drain electrode 54 is formed on the back surface 23 of the semiconductor substrate 10. The drain electrode 54 is formed of a conductive material such as metal.

The first trench body portion 63 is a region of a second conductivity type which is provided on the lower end of the gate trench portion 40 to cover a part of the bottom and the side surface of the gate trench portion 40. The first trench body portion 63 of the present example is of P+ type, as an example. By providing the first trench body portion 63, the breakdown voltage of the silicon carbide semiconductor device 100 can be improved.

The mesa body region 60 is a region of the second conductivity type which is provided to be in direct contact with the lower end of the base region 14 in a mesa portion between the adjacent gate trench portions 40. The mesa body region 60 of the present example is of P+ type, as an example. The mesa body region 60 of the present example includes a first mesa body portion 61 and a second mesa body portion 62. The mesa body region 60 may be formed by two steps of ion implantations or may be formed by a single step of ion implantation from the front surface 21 of the semiconductor substrate 10.

In the transistor portion 70 and the diode portion 80, the first mesa body portion 61 is provided at a portion lower than the lower end of the base region 14. The first mesa body portion 61 may be provided to have an upper end which is in direct contact with the lower end of the second mesa body portion 62. The first mesa body portion 61 may be simultaneously formed when the first trench body portion 63 is formed. In a depth direction of the semiconductor substrate 10, the first mesa body portion 61 may be formed at the same depth as the first trench body portion 63 or may be formed at a different depth. The lower end of the first mesa body portion 61 may be provided at a portion upper than the lower end of the first trench body portion 63.

The second mesa body portion 62 is provided between the base region 14 and the first mesa body portion 61 in the transistor portion 70. The second mesa body portion 62 is provided to have an upper end which is in direct contact with the lower end of the base region 14.

Each doping concentration of the first mesa body portion 61 and the second mesa body portion 62 may be equal to or greater than the doping concentration of the base region 14 or may be equal to or less than the doping concentration of the contact region 15. In an example, each doping concentration of the first mesa body portion 61 and the second mesa body portion 62 may be 1×10¹⁸ cm⁻³ or more or may be 4×10¹⁸ cm⁻³ or less.

When an avalanche is generated in the silicon carbide semiconductor device 100, an avalanche current greater than an operating current may flow into the gate trench portion 40. In the present example, by providing the mesa body region 60, the avalanche current can flow into the front surface 21 through the mesa body region 60 and the flow of the avalanche current into the gate trench portion 40 can be suppressed.

FIG. 2B is a representative drawing of an example of a Y-Z cross section of the silicon carbide semiconductor device 100 on the b-b′ line of FIG. 1. FIG. 2B is a Y-Z cross-sectional view of a region of the silicon carbide semiconductor device 100, in which the contact region 15 is provided in a top view. Difference from FIG. 2A will be described with FIG. 2B.

In FIG. 2B, the contact region 15 is formed on the entire surface of the front surface 21 of the semiconductor substrate 10. The contact region 15 may be provided to extend from the side wall of one adjacent gate trench portion 40 to the side wall of the other gate trench portion 40 in an arrangement direction of the gate trench portion 40.

In FIG. 2B, the base region 14 is formed on the entire surface on the bottom of the contact region 15, but there is no problem as long as the base region 14 is provided only in a vicinity of the gate trench portion 40 in an example. Even if the base region 14 is not provided on the entire surface on the bottom of the contact region 15, a path through which the avalanche current in the diode portion 80 flows can be limited and the breakage of the gate dielectric film 42 can be prevented, as long as a second conductivity type region 19 which will be described below is in contact with the contact region 15.

The connecting region 66 is a region of the second conductivity type which is provided below the contact region 15 in the transistor portion 70. The connecting region 66 of the present example is of P+ type, as an example. The connecting region 66 may connect the first mesa body portion 61 and the first trench body portion 63 at any place. The connecting region may be formed at the same depth as the first mesa body portion 61, or may be simultaneously formed when the first mesa body portion 61 is formed.

By providing the connecting region 66, a current path which goes through from the first mesa body portion 63 to the mesa body region 60, base region 14 and the contact region 15 can be formed. The connecting region 66 may be formed at any place of the transistor portion 70, for example, may be formed below the source region 12.

FIG. 2C is a representative drawing of an example of a Y-Z cross section of the silicon carbide semiconductor device 100 on the c-c′ line of FIG. 1. FIG. 2C is a Y-Z cross-sectional view of the silicon carbide semiconductor device 100 in the diode portion 80. The silicon carbide semiconductor device 100 of the present example includes a base region 14, a drift region 18, a buffer region 24, a dielectric film 38, a gate trench portion 40, a source electrode 52, a drain electrode 54, a first mesa body portion 61 and a trench body region 65.

The second conductivity type region 19 is a region of the second conductivity type which is provided to cover the side wall and the bottom surface of the gate trench portion 40 in the diode portion 80. The second conductivity type region includes the base region 14 and the trench body region 65. The second conductivity type region 19 may be provided to be exposed at the front surface 21 of the semiconductor substrate 10. The second conductivity type region 19 may be in direct contact with the dielectric film 38 on the front surface 21 of the semiconductor substrate 10. The second conductivity type region 19 may include a contact region 15 which is provided to contact the upper surface of the base region 14. That is, the second conductivity type region 19 may be provided to cover the side wall and the bottom surface of the gate trench portion 40 in the transistor portion 70. The contact region 15 may be in direct contact with the dielectric film 38 at the front surface 21 of the semiconductor substrate 10.

The trench body region 65 is a region of a second conductivity type which is provided on the lower end of the gate trench portion 40 to cover a part of the bottom and the side surface of the gate trench portion 40. The trench body region 65 of the present example is of P+ type, as an example. The trench body region 65 of the present example includes the first trench body portion 63 and the second trench body portion 64. The trench body region 65 may be formed by two steps of ion implantations or may be formed by a single step of ion implantation from the front surface 21 of the semiconductor substrate 10.

In the transistor portion 70 and the diode portion 80, the first trench body portion 63 is provided at a portion lower than the lower end of the base region 14. The first trench body portion 63 may be simultaneously formed when the first mesa body portion 61 is formed. The first trench body portion 63 is provided to have an upper end which is in direct contact with the lower end of the second trench body portion 64 in the diode portion 80. In the depth direction of the semiconductor substrate 10, the first trench body portion 63 may be formed at the same depth as the first mesa body portion 61 or may be formed at a different depth.

The second trench body portion 64 is provided between the base region 14 and the first trench body portion 63 in the diode portion 80. The second trench body portion 64 is provided to have an upper end which is in direct contact with the lower end of the base region 14.

When an avalanche is generated in the silicon carbide semiconductor device 100, an avalanche current greater than an operating current may flow into the gate trench portion 40. In the present example, by providing the second conductivity type region 19, the avalanche current can flow into the front surface 21 through the second conductivity type region 19 and the contact region 15 and the flow of the avalanche current into the gate trench portion 40 can be suppressed, and thus the breakage of the gate conductive portion 44 can be prevented.

The diode portion 80 of the present example is provided with the first mesa body portion 61. By providing the first mesa body portion 61 in the diode portion 80, the breakdown voltage of the silicon carbide semiconductor device 100 can be improved.

The diode portion 80 of the present example may be provided with the second mesa body portion 62. By not providing the second mesa body portion 62 in the diode portion 80, the resistance in the diode portion 80 can be reduced.

On the side wall of the gate trench portion 40, a width W19 of the second conductivity type region 19 in a trench arrangement direction may be uniform in the depth direction of the semiconductor substrate 10. W19 may be the same as a width of the gate dielectric film 42 or may be thicker than a width of the gate dielectric film 42. In an example, W19 may be 0.1 μm or more, or may be 0.3 or less.

FIG. 2D is a representative drawing of an example of an X-Z cross section of the silicon carbide semiconductor device 100 on the d-d′ line of FIG. 1. FIG. 2D is an X-Z cross sectional view of a region of the silicon carbide semiconductor device 100, which passes through the center of the adjacent gate trench portion 40.

In the depth direction of the semiconductor substrate 10, a thickness of the source region 12 may be thinner than a thickness of the contact region 15. In the depth direction of the semiconductor substrate 10, the lower end of the contact region 15 may be provided at a position deeper than the lower end of the source region 12. By reducing the thickness of the source region 12 to be thinner than the thickness of the contact region 15, a channel can be prevented from being formed between the source region 12 and the drift region 18 on the side wall of a gate trench portion 40.

The width of the base region 14 in a trench extending direction may be less than the total of a width of the contact region 15 in a trench extending direction and a width of the source region 12 in a trench extending direction. That is, there may be a relationship W14<W12+2×W15 established among the width W14 of the base region 14 in the trench extending direction, the width W15 of the contact region 15 and the width W12 of the source region 12. In this way, the electric field strength nearby the front surface 21 of the semiconductor substrate 10 can be reduced. In addition, the area of the base region 14 in a top view may be less than the total of the area of the contact region 15 and the area of the source region 12.

FIG. 2E is a representative drawing of an example of an X-Z cross section of the silicon carbide semiconductor device 100 on the e-e′ line of FIG. 1. FIG. 2E is an X-Z cross sectional view of a region of the silicon carbide semiconductor device 100, which passes through the second conductivity type region 19.

As represented by dashed-dotted lines in FIG. 2E, the silicon carbide semiconductor device 100 includes a diode portion 80 and a second conductivity type region 19. The second conductivity type region 19 includes the base region 14 and the trench body region 65. The second conductivity type region 19 may be provided on the entire surface of the diode portion 80 in a vicinity of the gate trench portion 40.

The second conductivity type region 19 may directly contact both of the adjacent contact regions 15 in the trench extending direction. The second conductivity type region 19 may be provided to extend from to one contact region 15 to the other contact region 15 in a vicinity of the gate trench portion 40 of the diode portion 80 which is provided between the adjacent transistor portions 70. In this way, the breakage of the gate conductive portion 44 can be prevented since the avalanche current can flow into the front surface 21 through the second conductivity type region 19 and the contact region 15 and the flow of the avalanche current into the gate trench portion 40 can be suppressed.

FIG. 2F is a representative drawing of an example of an X-Z cross section of the silicon carbide semiconductor device 100 on the f-f′ line of FIG. 1. FIG. 2F is an X-Z cross sectional view of a region of the silicon carbide semiconductor device 100, which does not pass through the mesa body region 60 or the trench body region 65.

As shown in FIG. 2F, a region of the second conductivity type with a high concentration is not provided below the diode portion 80 or the source region 12 which operates as a MOSFET in a vicinity of the gate trench portion 40. In this manner, by a design without providing the region being a channel with a second conductivity type region with a high concentration, effects such as avoiding the breakage of the gate conductive portion 44 during avalanche and suppressing leakage of current from the drain electrode 54 to the source electrode 52 can be realized without impairing the nature of the silicon carbide semiconductor device 100.

As shown in FIG. 2F, the connecting region 66 may be provided below the contact region 15. In this case, a second conductivity type region with high concentration is formed in a region being a channel of a region operating as a MOSFET, but by limiting the forming position of the connecting region 66, the nature of the silicon carbide semiconductor device 100 can be prevented from being impaired.

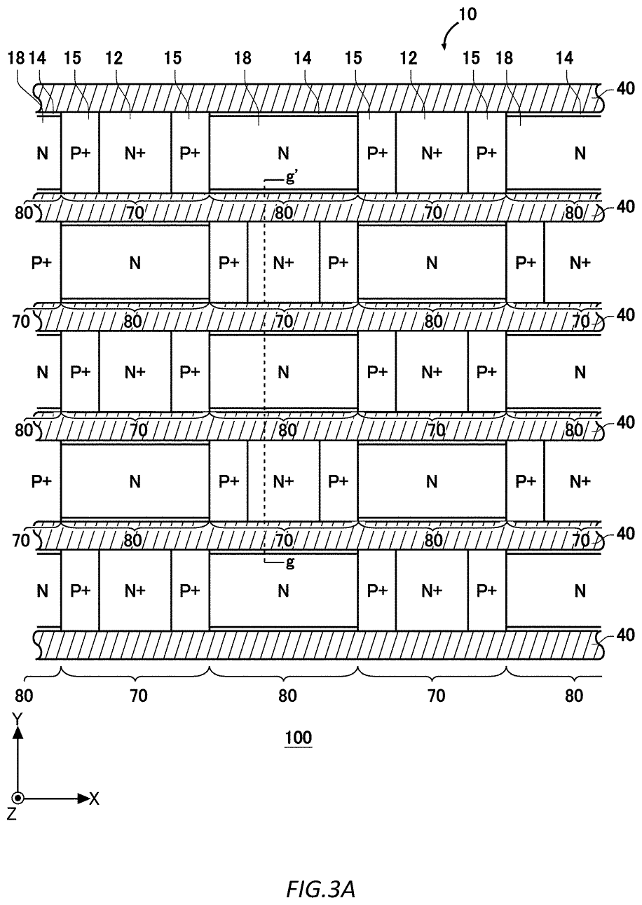

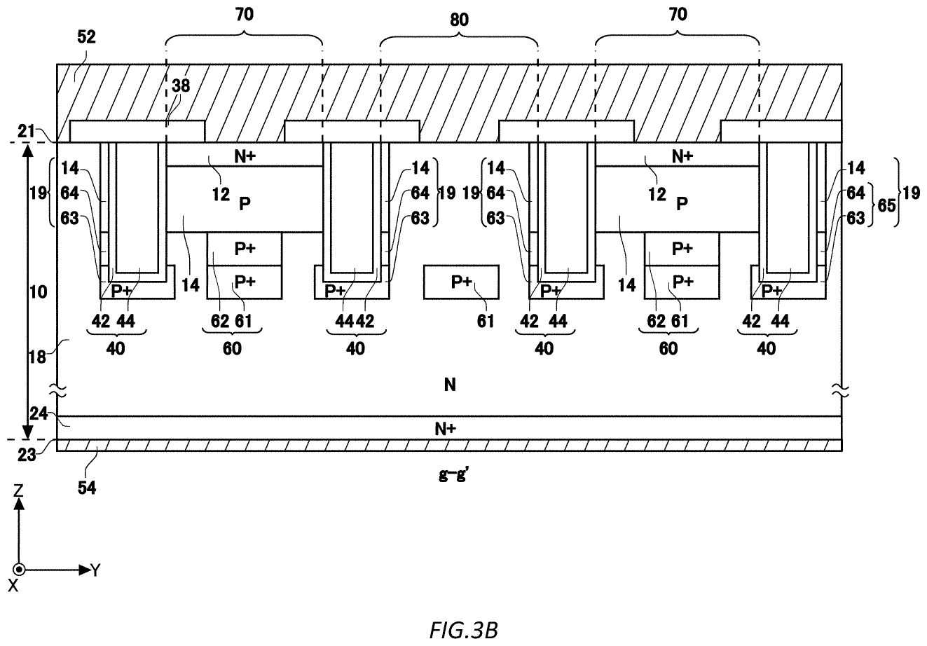

FIG. 3A is a representative drawing of a modification example of an upper surface of the silicon carbide semiconductor device 100. The configuration of the embodiment example of FIG. 3A is different from the configuration of the embodiment example of FIG. 1 in that the transistor portion 70 is sandwiching the gate trench portion 40 to face the diode portion 80 and the diode portion 80 is sandwiching the gate trench portion 40 to face the transistor portion 70. That is, as in FIG. 3A, the transistor portion 70 and the diode portion 80 may be provided in a staggered structure.

By providing the transistor portion 70 and the diode portion 80 in a staggered structure, turning on of the parasitic diode in the transistor portion 70 can be further suppressed. In this way, the characteristic deterioration of the silicon carbide semiconductor device 100 due to stacking fault extension can be efficiently suppressed.

FIG. 3B is a representative drawing of an example of a Y-Z cross section of the silicon carbide semiconductor device 100 on the g-g′ line of FIG. 3A. FIG. 3B is a Y-Z cross-sectional view of a region in which a source region 12 is provided on the front surface 21 of the semiconductor substrate 10 in the transistor portion 70 in FIG. 3A.

In the example of FIG. 3B, the first mesa body portion 61 is provided in all of the mesa portions, and the first trench body portion 63 is provided in all of the gate trench portions 40. On the other hand, the second mesa body portion 62 is provided only in the transistor portion 70, and not provided in the diode portion 80. In addition, the second trench body portion 64 is provided only in the diode portion 80, and not provided in the transistor portion 70. In addition, the second conductivity type region 19 of the diode portion 80 may be in direct contact with the contact region 15 of the transistor portion 70. In addition, the connecting region 66 may be provided at any place of the transistor portion 70 or the diode portion 80. In this way, extracting of the avalanche current which is previously described or the like can be performed while the characteristic deterioration of the silicon carbide semiconductor device 100 due to stacking fault extension is efficiently suppressed.

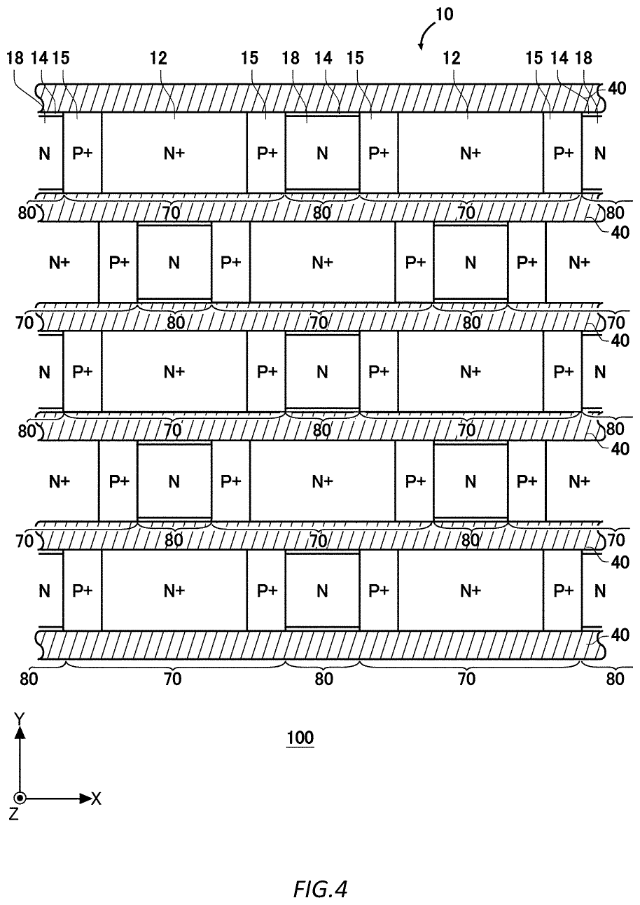

FIG. 4 is a representative drawing of a modification example of an upper surface of a silicon carbide semiconductor device 100. The configuration of the example of FIG. 4 is different from the configuration of FIG. 3A in that the area of the transistor portion 70 is greater than the area of the diode portion 80 in a top view while the transistor portion 70 and the diode portion 80 is provided in a staggered structure.

In an example, a ratio of the area of the transistor portion 70 to the area of the diode portion 80 in a top view may be 2:1, may be 3:1, or may be 4:1. By making the area of the transistor portion 70 greater than the area of the diode portion 80, the on-resistance of the silicon carbide semiconductor device 100 can be reduced. In an example, the area of the transistor portion 70 may be less than the area of the diode portion 80.

While the present invention has been described by way of the embodiments, the technical scope of the present invention is not limited to the above described embodiments. It is apparent to persons skilled in the art that various alterations or improvements can be made to the above described embodiments. It is also apparent from the description of the claims that the embodiments to which such alterations or improvements are made can be included in the technical scope of the present invention.

The operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10 semiconductor substrate
12 source region
14 base region
15 contact region
18 drift region
19 second conductivity type region
21 front surface
23 back surface
24 buffer region
38 dielectric film
40 gate trench portion
42 gate dielectric film
44 gate conductive portion
52 source electrode
54 drain electrode
60 mesa body region
61 first mesa body portion
62 second mesa body portion
63 first trench body portion
64 second trench body portion
65 trench body region
66 connecting region
70 transistor portion
80 diode portion
100 silicon carbide semiconductor device.

What is claimed is:

1. A silicon carbide semiconductor device comprising a transistor portion and a diode portion, comprising:
a semiconductor substrate;
a plurality of trench portions that are provided on a front surface of the semiconductor substrate;
a drift region of a first conductivity type that is provided on the semiconductor substrate; and
a second conductivity type region that covers a side wall and a bottom of a trench portion in the diode portion; wherein
the transistor portion and the diode portion are alternately arrayed along an extending direction of the trench portion in a mesa portion that is sandwiched between the plurality of trench portions.

2. The silicon carbide semiconductor device according to claim 1, wherein the transistor portion has a source region of a first conductivity type and a contact region of a second conductivity type on the front surface of the semiconductor substrate.

3. The silicon carbide semiconductor device according to claim 2, wherein in a depth direction of the semiconductor substrate, a thickness of the source region is thinner than a thickness of the contact region.

4. The silicon carbide semiconductor device according to claim 2, including a base region of the second conductivity type that is provided above the drift region and below the source region and the contact region.

5. The silicon carbide semiconductor device according to claim 4, wherein a width in the extending direction of the trench portion of the base region is smaller than a total of a width of the contact region in the extending direction of the trench portion and a width of the source region in the extending direction of the trench portion.

6. The silicon carbide semiconductor device according to claim 4, wherein an area of the base region is smaller than a total of an area of the contact region and an area of the source region in a top view.

7. The silicon carbide semiconductor device according to claim 4, wherein the base region is provided to be in direct contact with the side wall of the trench portion in the diode portion at the front surface of the semiconductor substrate.

8. The silicon carbide semiconductor device according to claim 2, wherein the second conductivity type region and the contact region are directly contacting in the extending direction of the trench portion.

9. The silicon carbide semiconductor device according to claim 4, comprising a mesa body region of the second conductivity type in the mesa portion along the extending direction of the trench portion, which is provided to contact a lower end of the base region.

10. The silicon carbide semiconductor device according to claim 9, wherein the mesa body region includes:
a first mesa body portion that is provided in the transistor portion and the diode portion;
a second mesa body portion that is provided above the first mesa body portion in the transistor portion and having an upper end which is in direct contact with the lower end of the base region; wherein
an upper end of the first mesa body portion is in direct contact with a lower end of the second mesa body portion in the transistor portion.

11. The silicon carbide semiconductor device according to claim 10, wherein each doping concentration of the first mesa body portion and the second mesa body portion is equal to or greater than a doping concentration of the base region or equal to or less than a doping concentration of the contact region.

12. The silicon carbide semiconductor device according to claim 10, wherein each doping concentration of the first mesa body portion and the second mesa body portion is 1×10¹⁸ cm⁻³ or more and 4×10¹⁸ cm⁻³ or less.

13. The silicon carbide semiconductor device according to claim 4, comprising a trench body region of the second conductivity type that is provided to cover the bottom and the side wall of the plurality of trench portions and that has a doping concentration higher than that of the base region.

14. The silicon carbide semiconductor device according to claim 13, wherein the trench body region includes:
a first trench body portion that is provided in the transistor portion and the diode portion; and
a second trench body portion that is provided above the first trench body portion in the diode portion and having an upper end which is in direct contact with a lower end of the base region; wherein
an upper end of the first trench body portion is provided to be in direct contact with a lower end of the second trench body portion in the diode portion.

15. The silicon carbide semiconductor device according to claim 14, wherein the second conductivity type region includes the first trench body portion, the second trench body portion and the base region.

16. The silicon carbide semiconductor device according to claim 14, wherein the second conductivity type region includes the first trench body portion, the second trench body portion, the base region and the contact region.

17. The silicon carbide semiconductor device according to claim 1, wherein a thickness of the second conductivity type region is 0.1 μm or more, or 0.3 μm or less on the side wall of the trench portion.

18. The silicon carbide semiconductor device according to claim 4, wherein the base region is provided between the source region and the trench portion on the front surface of the semiconductor substrate.

19. The silicon carbide semiconductor device according to claim 2, wherein
The transistor portion sandwiches the trench portion to face the diode portion, and
The diode portion sandwiches the trench portion to face the transistor portion.

20. The silicon carbide semiconductor device according to claim 19, wherein an area of the transistor portion is greater than an area of the diode portion in a top view.
